(19) United States
(12) Patent Application Publication
(10) Pub. No.: US 2012/0100687 A1
(43) Pub. Date: Apr. 26, 2012

(54) METHODS FOR FABRICATING CAPACITOR AND METHODS FOR FABRICATING SEMICONDUCTOR DEVICE INCLUDING THE CAPACITOR

(75) Inventors: Hanjin Lim, Seoul (KR); Jong-Bom Seo, Seoul (KR); Seokwoo Nam, Incheon (KR); Bonghyun Kim, Incheon (KR); Yongjae Lee, Seongnam (KR); KiVin Im, Incheon (KR)

(73) Assignee: SAMSUNG ELECTRONICS CO., LTD., Suwon-si (KR)

(21) Appl. No.: 13/274,695

(22) Filed: Oct. 17, 2011

(30) Foreign Application Priority Data
Oct. 21, 2010 (KR) 10-2010-0103016

(51) Int. Cl. H01L 21/02

(52) U.S. Cl. 438/381; 257/E21.008

(57) ABSTRACT

Example embodiments relate to methods for fabricating a capacitor and methods for fabricating a semiconductor device including the capacitor. The methods for fabricating a capacitor may include forming a preliminary lower electrode with a first area on a substrate; implanting ions in the preliminary lower electrode to form a lower electrode with a second area that is larger or substantially larger than the first area; and forming a dielectric layer and an upper electrode on the lower electrode.

### CROSS-REFERENCE TO RELATED APPLICATION

This U.S. non-provisional patent application claims priority under 35 U.S.C. §119 to Korean Patent Application No. 10-2010-0103016, filed on Oct. 21, 2010, the entire contents of which are hereby incorporated by reference.

### BACKGROUND

The present disclosure herein relates to methods for fabricating a capacitor and methods for fabricating a semiconductor device including the capacitor, more particularly, to methods for fabricating a capacitor formed of metal or metal compound and methods for fabricating a semiconductor device including the capacitor.

Capacitors store charges and conventionally include a lower electrode formed into a cylindrical shape. To improve the capacitance of capacitors, the width of the lower electrode of cylindrical shape has become narrower. However, a lower electrode with a relatively narrow width has a higher occurrence of sidewall collapse.

### SUMMARY

Some example embodiments of the inventive concepts relate to methods for fabricating a capacitor that is more stable structurally and/or that has improved capacitance.

Some example embodiments of the inventive concepts also relate to methods for fabricating a semiconductor device including the capacitor.

A non-limiting embodiment of a method for fabricating a capacitor may include forming a preliminary lower electrode with a first area on a substrate; implanting ions in the preliminary lower electrode to form a lower electrode with a second area that is larger than the first area; and forming a dielectric layer and an upper electrode on the lower electrode.

In some embodiments, the implanting of the ions may be performed using boron or arsenic.

In other embodiments, the preliminary lower electrode may be formed to have a first width, and the lower electrode may be formed to have a second width that is narrower than the first width by the implanting of the ions.

In still other embodiments, the preliminary lower electrode may include metal or metal compound. The preliminary lower electrode may include at least one material selected from the group consisting of titanium nitride, tungsten nitride, tantalum nitride, platinum, rubidium, and iridium.

In even other embodiments, the preliminary lower electrode may be formed into hollow cylindrical shape with closed bottom.

In yet other embodiments, the preliminary lower electrode may be formed in a chemical vapor deposition process using titanium tetrachloride and ammonia, and chlorine and carbon in the preliminary lower electrode may be removed during the implanting of the ions.

In further embodiments, the preliminary lower electrode may have a first width, and the lower electrode may have a second width that is narrower than the first width.

A non-limiting method for fabricating a semiconductor device may include forming a transistor on a substrate, the transistor including a gate insulating layer, a gate electrode, a first impurity region, and a second impurity region; forming a bit line electrically connected with the first impurity region; and forming a capacitor electrically connected with the second impurity region. The forming of the capacitor may include forming a interlayer insulating layer on the bit line, the interlayer insulating layer having a hole; forming a preliminary lower electrode of a cylindrical shape on an inner wall of the hole, the preliminary lower electrode having a first radius; implanting ions in the preliminary lower electrode to form a lower electrode of a cylindrical shape with a second radius that is larger than the first radius; and forming a dielectric layer and an upper electrode on the lower electrode.

In some embodiments, the forming of the preliminary lower electrode may include forming a conductive layer on the interlayer insulating layer having the hole, the conductive layer partially filling the hole; forming a sacrificial layer filling the hole partially filled with the conductive layer; etching the conductive layer until a top surface of the interlayer insulating layer is exposed to form the preliminary lower electrode; and etching the interlayer insulating layer and the sacrificial layer. The interlayer insulating layer and the sacrificial layer may be etched by a LAL solution including ammonium fluoride, hydrofluoric acid, and water. During the etching of the interlayer insulating layer and the sacrificial layer by the LAL solution, the inner wall of the preliminary lower electrode may be dehydrated.

In other embodiments, the implanting of the ions may be performed using boron or arsenic.

### BRIEF DESCRIPTION OF THE DRAWINGS

The accompanying drawings are included to provide a further understanding of the inventive concepts, and are incorporated in and constitute a part of this specification. The drawings illustrate example embodiments of the inventive concepts and, together with the description, serve to explain principles of the inventive concepts. In the figures:

FIGS. 1 through 11 are cross-sectional views illustrating a method for fabricating a semiconductor device according to various embodiments of the inventive concepts;

FIGS. 8a and 9a are perspective views illustrating a preliminary lower electrode of FIG. 8 and a lower electrode of FIG. 9, respectively;

FIG. 12 is a graph comparing I-V characteristic between a comparison embodiment and a non-limiting embodiment of the inventive concepts;

FIG. 13 a block diagram illustrating a memory card formed with a memory device according to various embodiments of the inventive concepts; and

FIG. 14 is a block diagram illustrating a system including a memory device according to various embodiments of the inventive concepts.

### DETAILED DESCRIPTION

Example embodiments of the inventive concepts will be described below in more detail with reference to the accompanying drawings. The example embodiments of the inventive concepts may, however, be embodied in different forms and should not be construed as limited to the various embodiments set forth herein. Rather, the non-limiting embodiments herein are merely provided so that this disclosure will be more thorough and complete so as to fully convey the scope of the inventive concepts to those skilled in the art.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms, “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the inventive concepts will be described in detail with reference to the accompanying drawings.

(Method for Fabricating a Semiconductor Device)

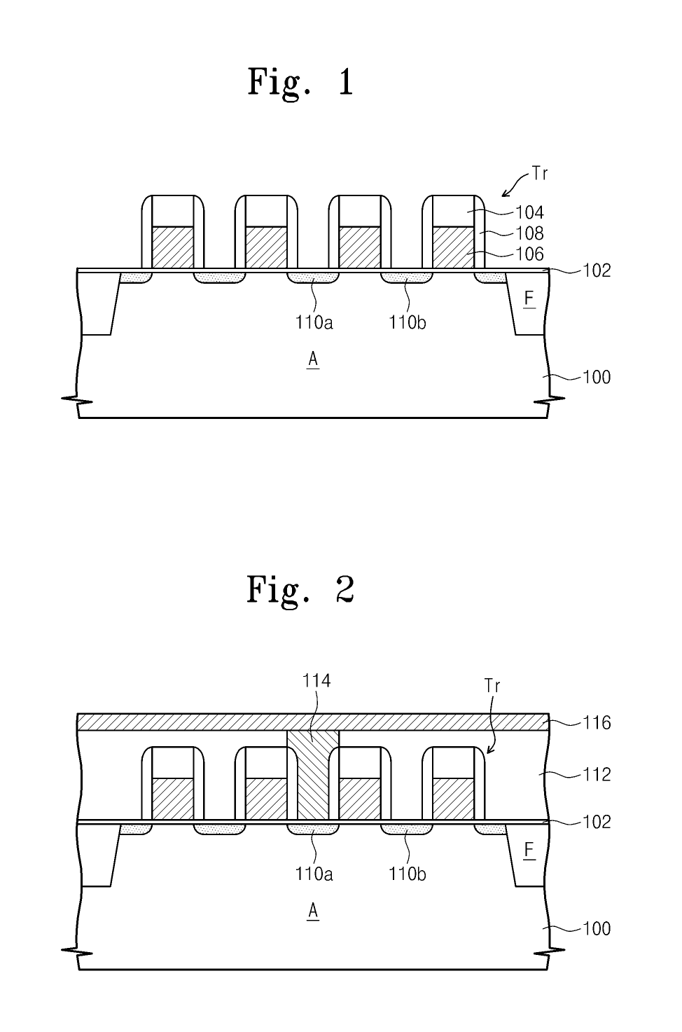

FIGS. 1 through 11 are cross-sectional views illustrating a method for fabricating a semiconductor device according to various embodiments of the inventive concepts.

Referring to FIG. 1, a transistor Tr may be formed on a substrate 100.

The substrate 100 may include silicon, germanium, or silicon/germanium. The substrate 100 may also be a silicon on insulation (SOI) substrate or a germanium on insulation (GOI) substrate.

A field region F may be formed on the substrate 100 using a shallow trench isolation process to define an active region A. The field region F may be formed of an oxide, a nitride, or an oxynitride.

A gate insulating layer 102 may be formed on the substrate 100. The gate insulating layer 102 may include an oxide and may be formed by a thermal oxidation process. A first conductive layer and a mask 104 may be sequentially formed on the gate insulating layer 102. The first conductive layer may be etched using the mask 104 as an etching mask to form a gate electrode 106 which extends in a first direction and has a linear shape. Spacers 108 may be formed on sidewalls of the gate electrode 106 and mask 104. Impurities may be injected into the substrate adjacent to the sidewalls of the gate electrode 106 such that first and second impurity regions 110a and 110b are formed. The transistor formed by the above processes may have a planar structure.

The gate electrode 106 may have a bottom surface that is lower or substantially lower than the top surface of the substrate 100 such that the transistor Tr has a recessed channel. Alternatively, the transistor Tr may have a pillar active pattern and a vertical channel extending in the first direction to connect the pillar active pattern.

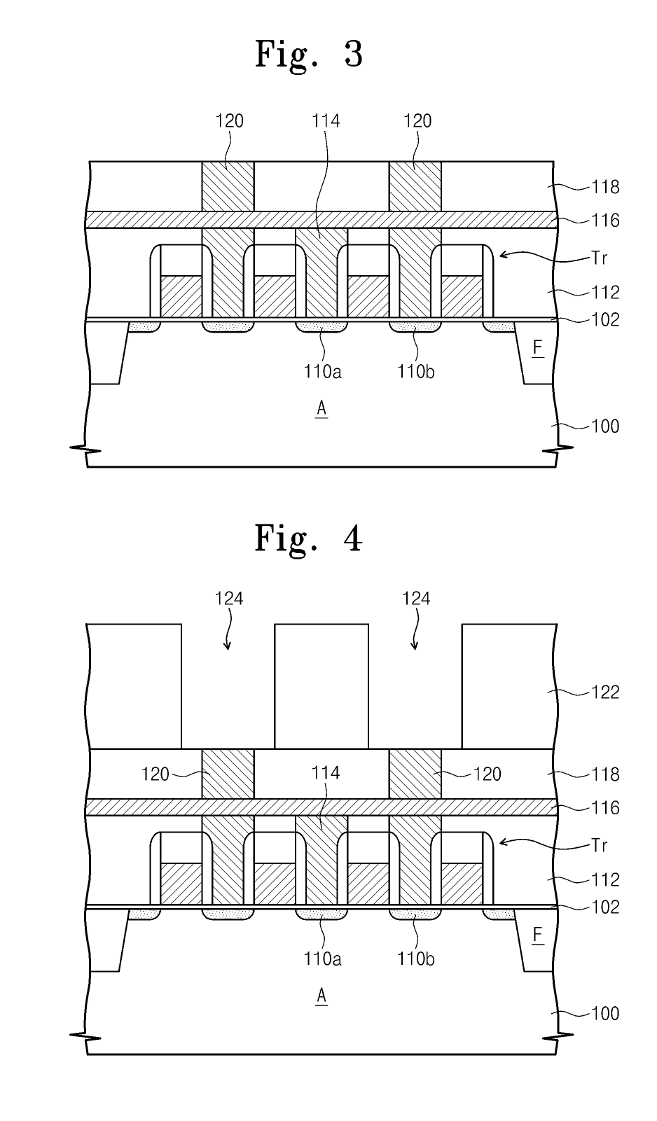

Referring to FIG. 2, a first interlayer insulating layer 112 may be formed and a bit line 116 may be formed on the first interlayer insulating layer 112.

The first interlayer insulating layer 112 may be formed on the substrate 100 and transistors Tr to fill a space between the transistors Tr. The first interlayer insulating layer 112 may include an oxide, a nitride, or an oxynitride.

The first interlayer insulating layer 112 may be partially etched to form a first contact hole exposing the first impurity region 110a. A conductive layer may be filled in the first contact hole to form a first contact 114. A second conductive layer may be formed on the first interlayer insulating layer 112 with the first contact 114, and patterned to form the bit line 116 which extends in a second direction. The second direction may be perpendicular to the first direction. The first contact 114 may connect the first impurity region 110a and the bit line 116.

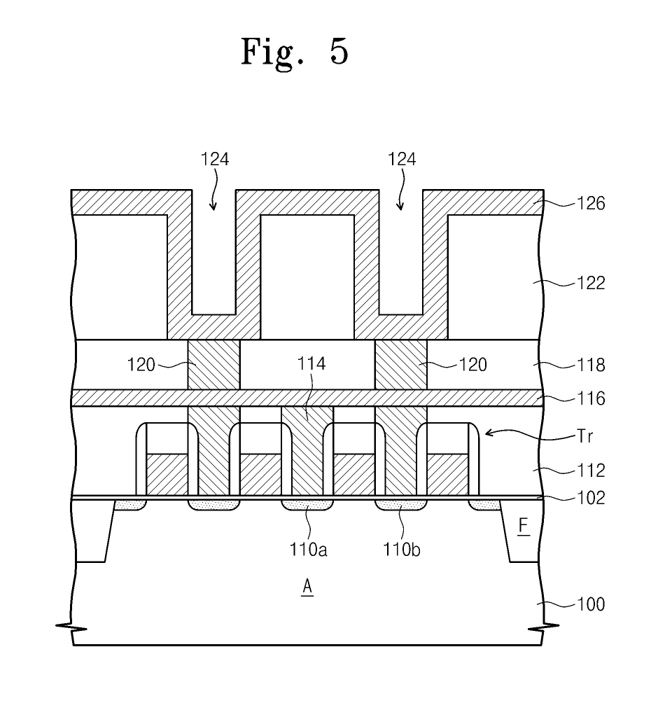

Referring to FIG. 3, a second interlayer insulating layer 118 may be formed on the bit line 116. Afterwards, a second contact 120 may be formed.

The second interlayer insulating layer 118 may be formed on the first interlayer insulating layer 112 to fill a space between the bit lines 116. The second interlayer insulating layer 118 may be formed of substantially the same material as the first interlayer insulating layer 112. For example, the second interlayer insulating layer 118 may include an oxide, a nitride or an oxynitride.

The first and the second interlayer insulating layers 112 and 118 may be partially etched to form a second contact hole exposing the second impurity region 110b. A conductive layer may be filled in the second contact hole to form a second contact 120.

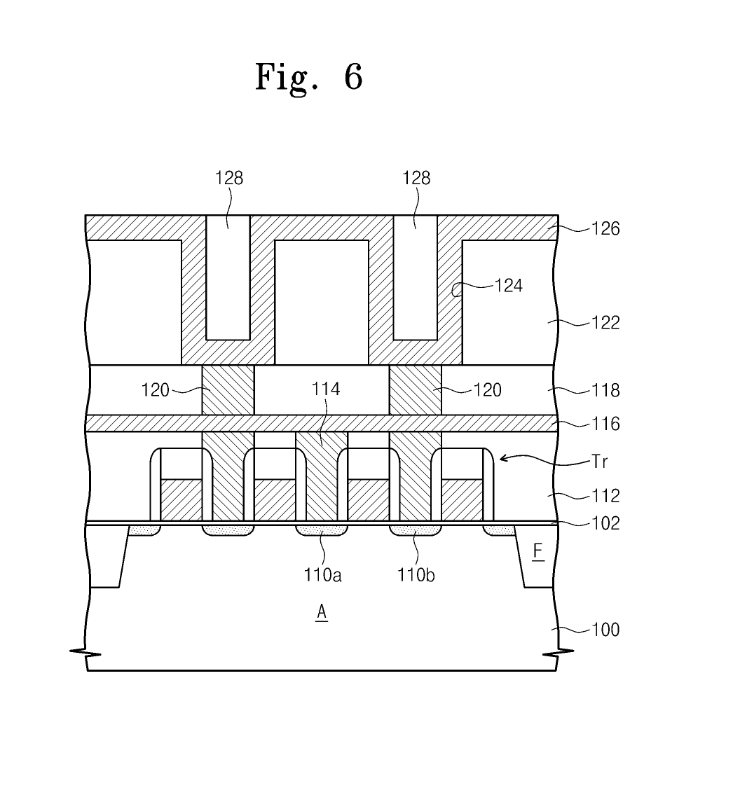

Referring to FIG. 4, a third interlayer insulating layer 122 may be formed. The third interlayer insulating layer 122 has a hole 124 exposing a top surface of the second contact 120. The third interlayer insulating layer 122 may be formed of substantially the same material as the first and the second interlayer insulating layers 112 and 118. For example, the third interlayer insulating layer 122 may include an oxide, a nitride or an oxynitride. The third interlayer insulating layer 122 may be partially etched to form the hole 124 exposing the second contact 120.

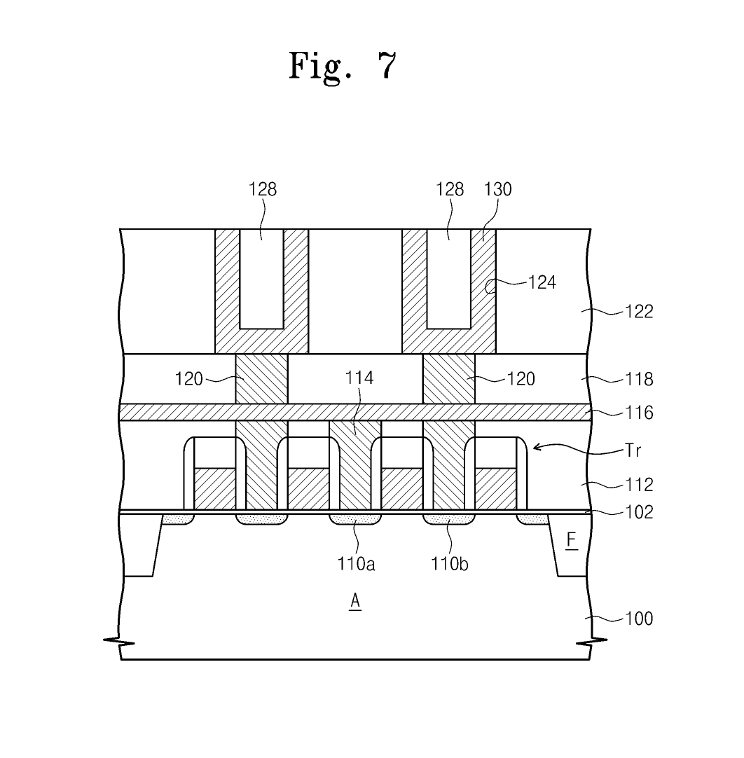

Referring to FIG. 5, a third conductive layer 126 may be conformally formed on the third interlayer insulating layer 122 and the hole 124.

The third conductive layer 126 may be formed to only partially fill the hole 124 while being continuously formed along the surface profile of the third interlayer insulating layer 122. The third conductive layer 126 may include a metal or a metal compound. For example, the third conductive layer 126 may include at least one material selected from the group consisting of titanium nitride, tungsten nitride, tantalum nitride, platinum, and iridium. The third conductive layer 126 including titanium nitride may be formed on the third interlayer insulating layer 122 by a chemical vapor deposition (CVD) process or an atomic layer deposition (ALD) process using titanium tetrachloride and ammonia gas. Chlorine or carbon may be present in the third conductive layer.

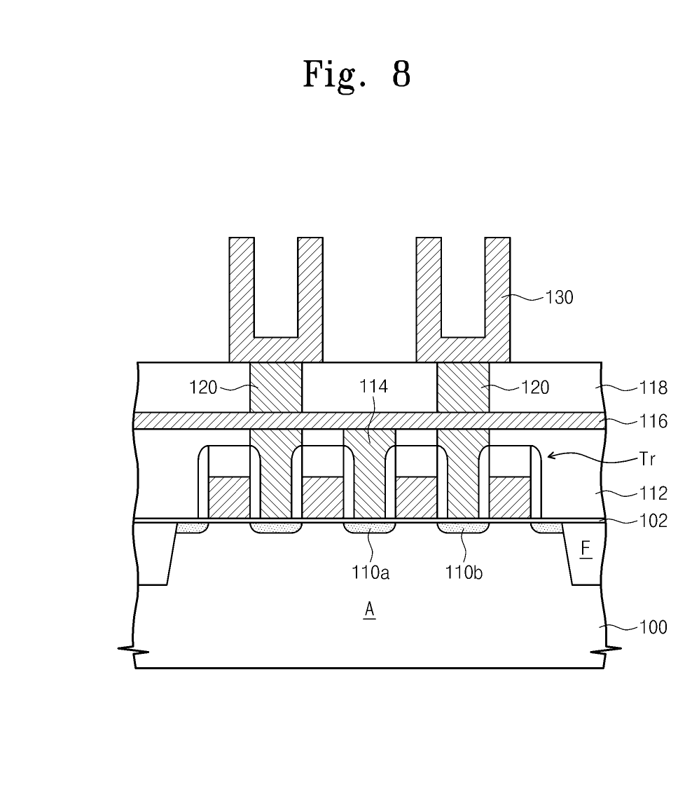

Referring to FIG. 6, a sacrificial layer 128 may be formed on the third interlayer insulating layer 122 to fill the hole 124 in which the third conductive layer 126 is formed. The sacrificial layer 128 may be formed of substantially the same material as the third interlayer insulating layer 122. For example, the sacrificial layer 128 may include an oxide.

An upper portion of the sacrificial layer 128 may be partially etched to expose a top surface of the third conductive layer 126.

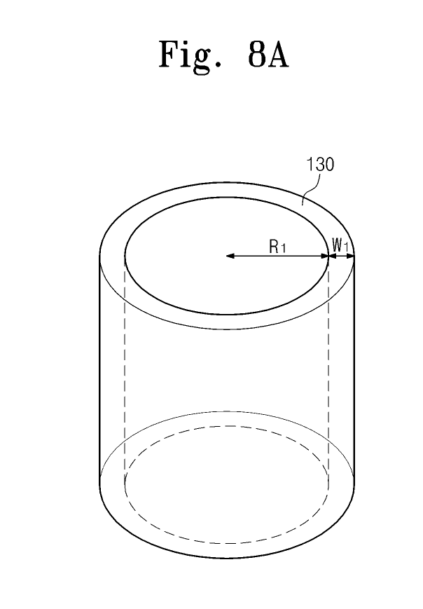

Referring to FIG. 7, the exposed third conductive layer 126 may be etched into separate nodes, thereby forming a preliminary lower electrode 130.

According to various embodiments of the inventive concepts, the preliminary lower electrode 130 may be formed into a hollow cylindrical shape with a closed bottom.

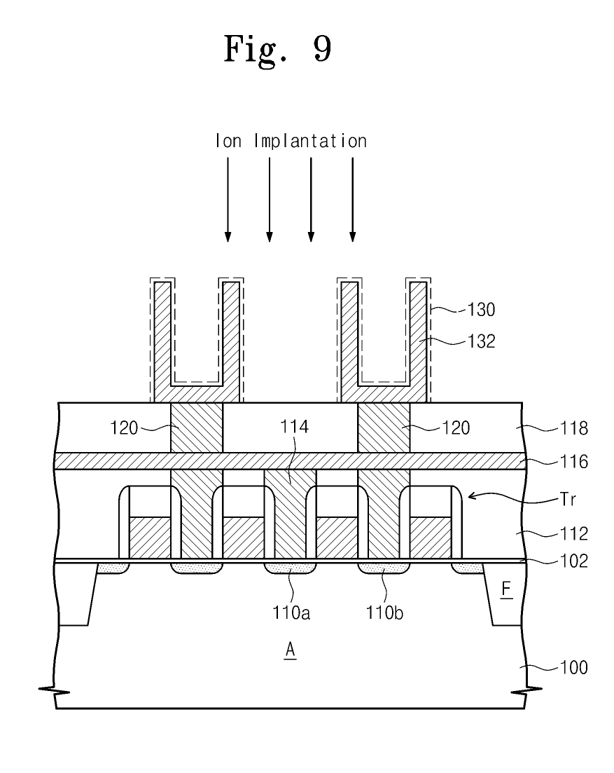

Referring to FIGS. 8 and 8a, the third interlayer insulating layer 122 and the sacrificial layer 128 are removed to expose the inner and outer walls of the preliminary lower electrode 130. When the third interlayer insulating layer 122 and the sacrificial layer 128 include an oxide, the third interlayer insulating layer 122 and the sacrificial layer 128 may be removed by a wet etch process using a buffered hydrofluoric acid. The preliminary lower electrode 130 may have a first radius of R₁, and the preliminary lower electrode 130 may have a total first area (e.g., first surface area) including the inner and outer surfaces. The preliminary lower electrode 130 may have a first width W₁.

The third interlayer insulating layer 122 and the sacrificial layer 128 may be etched by a LAL solution including ammonium fluoride, hydrofluoric acid, and water. During the etching of the third interlayer insulating layer 122 and the sacrificial layer 128 by the LAL solution, the inner wall of the preliminary lower electrode 130 may become dehydrated. Occasionally, the preliminary lower electrode 130 may collapse inward as a result of the cohesion of water at the inner opposing walls. When the width of the preliminary lower electrode 130 is relatively small, the preliminary lower electrode 130 may collapse or fall down because of cohesion. Thus, the first width W₁ may be rendered sufficiently large to reduce the risk of cohesion.

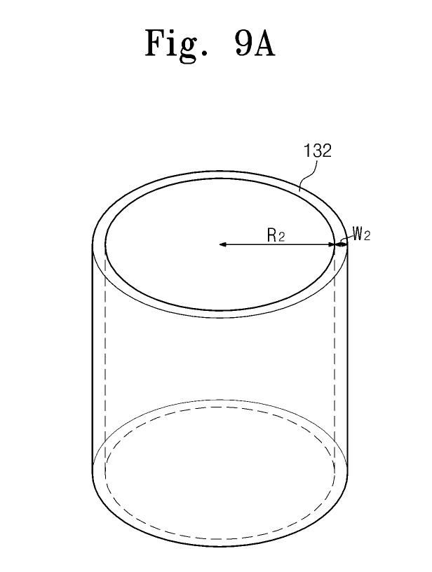

Referring to FIGS. 9 and 9a, an ion implantation into the preliminary lower electrode 130 may be performed to form a lower electrode 132 having a second area (e.g., second surface area). The second area may be larger or substantially larger than the first area.

The ion implantation may be performed to inject arsenic or boron. According to various embodiments, an injection angle of the ion implantation may be perpendicular with the surface of the substrate 100. According to other non-limiting embodiments of the inventive concepts, the injection angle may be tilted with respect to the surface of the substrate 100. When boron or arsenic ions are injected into the preliminary lower electrode 130, impurities in the preliminary lower electrode 130 can be removed. Thus, the lower electrode 132 with the second width W₂ (that is thinner or substantially thinner than the first width W₁) can be formed from the preliminary lower electrode 130 with the first width W₁. More specifically, if the preliminary lower electrode 130 includes titanium nitride as described with reference to FIG. 5, chlorine or carbon may be present in the preliminary lower electrode 130. The chlorine or carbon in the preliminary lower electrode 130 may be removed by the boron or arsenic ion implantation. Thus, the structure of the titanium nitride can be rendered more dense by the removal of the chlorine or carbon. Accordingly, the lower electrode 132 may have a second width W₂ that is narrower than the first width W₁ of the preliminary lower electrode 130 as well as a second radius of R₂ that is larger than the first radius R₁ of the preliminary lower electrode 130. Therefore, the lower electrode 132 may have a larger area than the preliminary lower electrode 130. For example, the lower electrode 132 may have a larger inner surface area than the preliminary lower electrode 130 as well as opposing inner walls that are spaced further apart than those of the preliminary lower electrode 130.

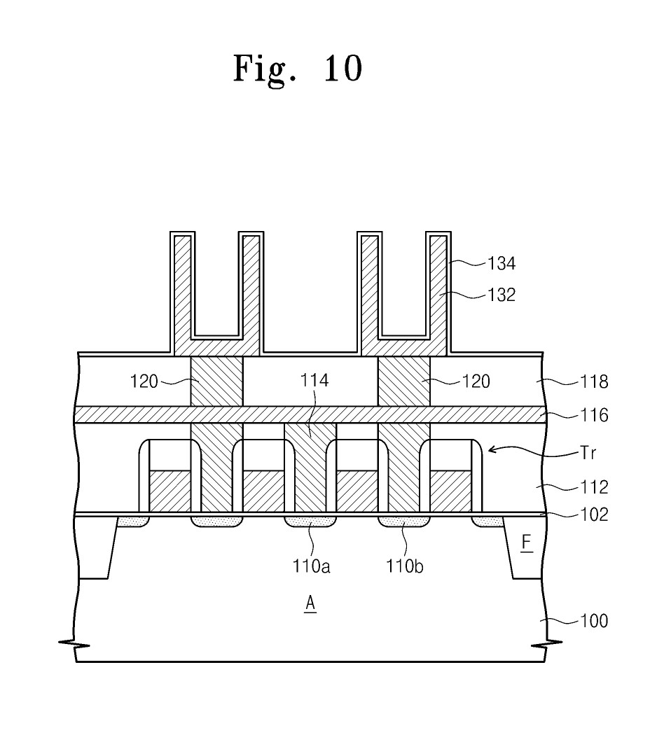

Referring to FIG. 10, a dielectric layer 134 may be conformally formed on the lower electrode 132.

The dielectric layer 134 may be conformally and continuously formed along the profile of the lower electrode 132 while not completely filling the inside of the lower electrode 132. The dielectric layer 134 may include a metal oxide. For example, the metal oxide may be a hafnium oxide, zirconium oxide, tantalum oxide, titanium oxide, aluminum oxide, or other suitable materials.

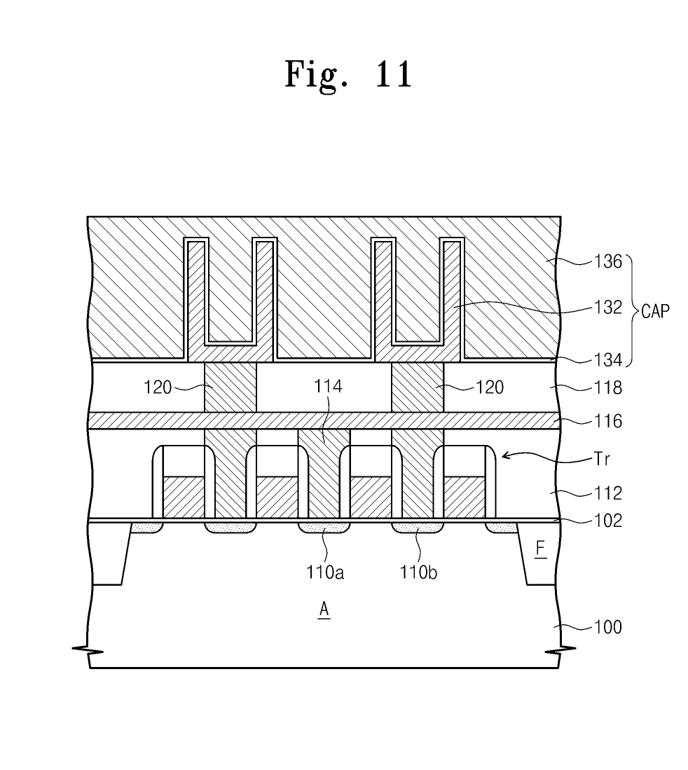

Referring to FIG. 11, an upper electrode 136 may be formed on the dielectric layer 134 to fill the lower electrode 132.

The upper electrode 136 may include substantially the same material as the lower electrode 132. The upper electrode 136 may include at least one material selected from the group consisting of titanium nitride, tungsten nitride, tantalum nitride, platinum, rubidium, and iridium.

Thereby, a capacitor CAP including the lower electrode 132, the dielectric layer 134, and an upper electrode 136 may be formed. According to various embodiments of the inventive concepts, the preliminary lower electrode 130 has a sufficient first width W₁ so as to avoid collapsing during the wet etching process for removing the sacrificial layer 128 and the third interlayer insulating layer 122. After performing the wet etching process, an ion implantation process using boron or arsenic is performed to form the lower electrode 132 with the second width W₂ that is narrower than the first width W₁ of the preliminary lower electrode 130. Thus, the lower electrode 132 has a greater area than the preliminary lower electrode 130 such that the contact area with the dielectric layer 134 is increased to improve the capacitance of the capacitor CAP.

The capacitor CAP may be formed into a cylindrical shape. However, the capacitor CAP according to example embodiments of the inventive concepts is not limited to this shape. For example, the capacitor CAP may be formed into a stack structure which includes, sequentially stacked, a lower electrode, a dielectric layer and the upper electrode. Alternatively, the capacitor CAP may be formed into a concave structure which includes a lower electrode of concave shape, a dielectric layer and an upper electrode stacked along the surface profile of the lower electrode.

### Experimental Embodiment

Table 1 shows a width of the lower electrode in a non-limiting embodiment and a comparison example.

TABLE 1

| | Embodiment | Comparison |
|---|---|---|
| Upper portion of the lower electrode | 70 Å | 75 Å |
| Lower portion of the lower electrode | 60 Å | 66 Å |

The lower electrode of the comparison example may be the preliminary lower electrode 130 of FIG. 8a. The widths of the upper portion and the lower portion of the lower electrode of the comparison example were respectively 75 Å and 66 Å.

The non-limiting embodiment in Table 1 may be the lower electrode 132 that formed by injecting boron ions into the preliminary lower electrode 130 as shown in FIG. 9a. The width of the upper portion and the lower portion of the non-limiting embodiment were respectively 70 Å and 60 Å

Table 1 show that the width of the lower electrode 132 was reduced after injecting the boron ions. As the lower electrode is reduced in width, the contact area between the lower electrode 132 and the dielectric layer 134 can be increased. Therefore, the capacitance of the capacitor CAP can be increased.

Table 2 shows the capacitance of the lower electrode in two non-limiting embodiments and a comparison example.

TABLE 2

| | Capacitance |
|---|---|
| Comparison | 17.2 fF/cell |
| Embodiment 1 | 18.0 fF/cell |
| Embodiment 2 | 18.0 fF/cell |

The lower electrode in the comparison example may be the preliminary lower electrode 130 shown in FIG. 8a. The capacitance of the lower electrode in the comparison example was 17.2 fF/cell

The non-limiting embodiment 1 may be the lower electrode 132 formed by injecting boron ions into the preliminary lower electrode 130 as shown in FIG. 9a. The capacitance of the lower electrode 132 was 18.0 fF/cell.

The non-limiting embodiment 2 may be the lower electrode 132 formed by injecting arsenic ions into the preliminary lower electrode 130 as shown in FIG. 9a. The capacitance of the lower electrode 132 was 18.0 fF/cell.

The lower electrode 132 is reduced in width after injecting the boron or arsenic ions. Thus, the contact area between the lower electrode 132 and the dielectric layer 134 can be increased by decreasing a wall thickness of the lower electrode 132. Therefore, the capacitance of the capacitor can be increased.

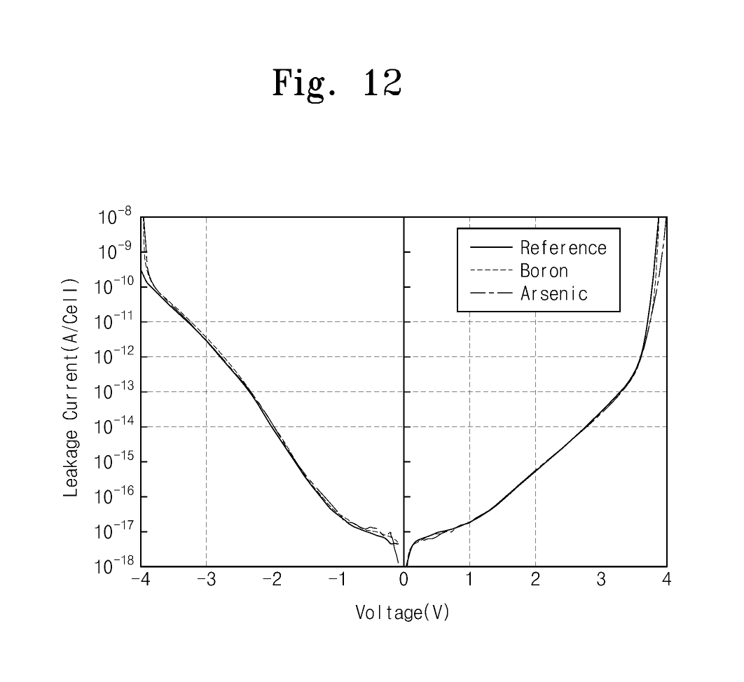

FIG. 12 is a graph comparing I-V characteristic between a comparison example and two non-limiting embodiments of the inventive concepts. The lower electrode in the comparison example may be the preliminary lower electrode 130 of FIG. 8a. Thus, boron or arsenic ions have not been injected into the comparison example. The non-limiting embodiment 1 may be a lower electrode 132 formed by injecting boron ions into the preliminary lower electrode 130, and the non-limiting embodiment 2 may be a lower electrode 132 formed by injecting arsenic ions into the preliminary lower electrode 130.

Referring to FIG. 12, the difference in the I-V characteristics is not particularly significant between the comparison example and the non-limiting embodiments. Thus, increasing capacitance with ion injection does not result in a deterioration of electrical characteristics.

### Practical Embodiment

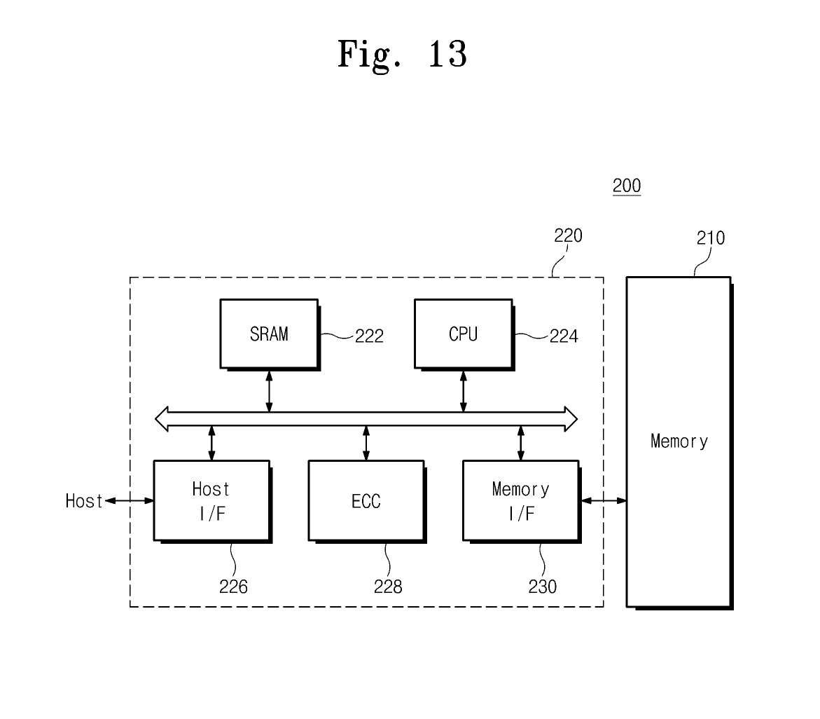

FIG. 13 a block diagram illustrating a memory card formed with a memory device according to various embodiments of the inventive concepts.

Referring to FIG. 13, the semiconductor device according to various embodiments of the inventive concepts may be applied to a memory card 200. For example, the memory card 200 may include a memory controller 220 which controls data exchanging between a host and a memory 210. A SRAM 222 may be used as an operation memory of a CPU (224). A host interface 226 may have a data exchanging protocol of a host connecting with the memory card 200. An error correcting code 228 may detect and correct errors which are included in data read from the memory 210. The memory interface 230 may interface with the memory 210. The CPU 224 performs a control operation for data exchanging of the memory controller 220. Since the memory 210 applied to the memory card 200 is fabricated in accordance with example embodiments of the inventive concepts, the memory card 200 can have a capacitor with improved capacitance without having an increased risk of a collapse caused by the structure.

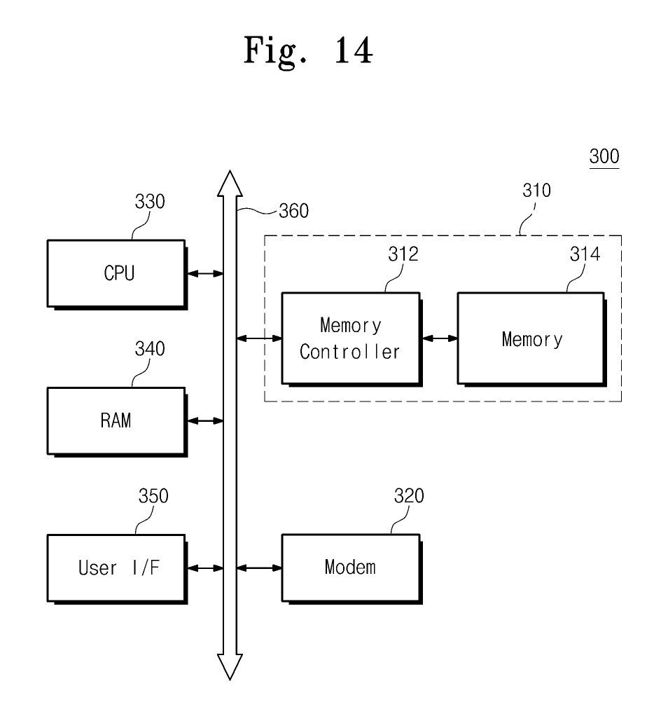

FIG. 14 is a block diagram illustrating a system including a memory device according to various embodiments of the inventive concepts.

Referring to FIG. 14, a data processing system 300 may include a memory system 310 which includes a semiconductor memory device according to various embodiments of the inventive concepts. The data processing system 300 may be a mobile device or a computer. For example, the data processing system 300 may include the memory system 310, a modem 320, a CPU 330, a RAM 340, an user interface 350 which are respectively connected to a system bus 360. The memory system 310 stores data processed by the CPU 330 or external data. The memory system 310 may include a memory 314 and a memory controller 312. The memory system 310 may be the memory card of FIG. 13. The data processing system 300 may be provided as a memory card, a solid state disk, a camera image sensor, and other application chipset. For example, the memory system 310 may be formed into the solid state disk such that the data processing system 300 stores a relatively large volume of data in the memory system 310 in a stable and reliable manner.

According to example embodiments of the inventive concepts, the collapse of a preliminary lower electrode may be avoided during a wet etching process for removing the sacrificial layer and the third interlayer insulating layer, because the preliminary lower electrode has a sufficient width. The lower electrode can have a relatively large area compared to the preliminary lower electrode as a result of the ion implantation process using boron or arsenic, and a contact area with the dielectric layer is increased to improve the capacitance of the capacitor.

The above-disclosed subject matter is to be considered merely illustrative and not restrictive, and the appended claims are intended to cover all such modifications, enhancements, and other embodiments, which fall within the spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

What is claimed is:

1. A method for fabricating a capacitor, the method comprising:
forming a preliminary lower electrode with a first area on a substrate;
implanting ions in the preliminary lower electrode to form a lower electrode with a second area that is larger than the first area; and
forming a dielectric layer and an upper electrode on the lower electrode.

2. The method of claim 1, wherein the implanting ions is performed using boron or arsenic.

3. The method of claim 1, wherein the forming a preliminary lower electrode includes forming the preliminary lower electrode to have a first width, and
the implanting ions includes forming the lower electrode to have a second width that is narrower than the first width.

4. The method of claim 1, wherein the preliminary lower electrode comprises a metal or metal compound.

5. The method of claim 1 wherein the preliminary lower electrode comprises at least one of titanium nitride, tungsten nitride, tantalum nitride, platinum, rubidium, and iridium.

6. The method of claim 1, wherein the forming a preliminary lower electrode includes forming a hollow cylindrical shape with a closed bottom.

7. The method of claim 1, wherein the forming a preliminary lower electrode includes a chemical vapor deposition process using titanium tetrachloride and ammonia, the preliminary lower electrode containing at least one of chlorine and carbon, and
the implanting ions includes removing at least one of the chlorine and carbon in the preliminary lower electrode with the ions.

8. The method of claim 1, wherein the preliminary lower electrode has a first width, and the lower electrode has a second width that is narrower than the first width.

9. A method for fabricating a semiconductor device, the method comprising:
forming a transistor on a substrate, the transistor including a gate insulating layer, a gate electrode, a first impurity region, and a second impurity region;
forming a bit line electrically connected with the first impurity region; and
forming a capacitor electrically connected with the second impurity region, the forming a capacitor including,
forming an interlayer insulating layer on the bit line, the interlayer insulating layer having a hole;
forming a preliminary lower electrode of a cylindrical shape on an inner wall of the hole, the preliminary lower electrode having a first radius;
implanting ions in the preliminary lower electrode to form a lower electrode, the lower electrode having a cylindrical shape with a second radius that is larger than the first radius; and
forming a dielectric layer and an upper electrode on the lower electrode.

10. The method of claim 9, wherein the forming a preliminary lower electrode comprises:
forming a conductive layer on the interlayer insulating layer to partially fill the hole;
forming a sacrificial layer to fill the hole partially filled with the conductive layer;
etching the conductive layer until a top surface of the interlayer insulating layer is exposed to form the preliminary lower electrode; and
etching the interlayer insulating layer and the sacrificial layer.

11. The method of claim 10, wherein the etching the interlayer insulating layer and the sacrificial layer includes a LAL solution including ammonium fluoride, hydrofluoric acid, and water.

12. The method of claim 10, wherein an inner wall of the preliminary lower electrode becomes dehydrated during the etching the interlayer insulating layer and the sacrificial layer.

13. The method of claim 9, wherein the implanting ions is performed using boron or arsenic.

14. A method for fabricating a capacitor, the method comprising:
forming a preliminary lower electrode, the preliminary lower electrode having a first inner area;
forming a lower electrode by implanting ions into the preliminary lower electrode to increase the first inner area to a second inner area; and
forming a dielectric layer and an upper electrode on the lower electrode.

15. The method of claim 14, wherein the implanting ions includes increasing a density of a base material of the preliminary lower electrode.

16. The method of claim 14, wherein the implanting ions includes decreasing a sidewall thickness of the preliminary lower electrode.

17. The method of claim 14, wherein the implanting ions includes increasing an inner radius of the preliminary lower electrode.

18. The method of claim 14, wherein the implanting ions includes implanting at least one of boron ions and arsenic ions into the preliminary lower electrode.

19. The method of claim 14, wherein the implanting ions includes removing elements in the preliminary lower electrode with the ions.

20. The method of claim 19, wherein the removing elements includes removing at least one of chlorine and carbon from the preliminary lower electrode.
